(19) United States
(12) Patent Application Publication
(10) Pub. No.: US 2013/0111297 A1
(43) Pub. Date: May 2, 2013

(54) Systems and Methods for Symbol Selective Scaling in a Data Processing Circuit

(71) Applicants: Weijun Tan, Longmont, CO (US); Kelly Fitzpatrick, Sudbury, MA (US); Shaohua Yang, San Jose, CA (US); Fan Zhang, Milpitas, CA (US)

(72) Inventors: Weijun Tan, Longmont, CO (US); Kelly Fitzpatrick, Sudbury, MA (US); Shaohua Yang, San Jose, CA (US); Fan Zhang, Milpitas, CA (US)

(73) Assignee: LSI Corporation

(21) Appl. No.: 13/284,826

(22) Filed: Oct. 28, 2011

(51) Int. Cl. H03M 13/09

(52) U.S. Cl. 714/758; 714/E11.03

(57) ABSTRACT

Various embodiments of the present invention provide systems and methods for data processing. As an example, a data processing system is discussed that includes: a data detector circuit, a symbol selective scaling circuit, and a data decoder circuit. The data detector circuit is operable to apply a data detection algorithm to a data input guided by a first data set derived from a decoded output to yield a detected output. The symbol selective scaling circuit is operable to selectively scale one or more symbols of a second data set derived from the detected output to yield a scaled data set. The data decoder circuit operable to apply a data decode algorithm to a third data set derived from the scaled data set to yield the decoded output.

### BACKGROUND OF THE INVENTION

The present invention is related to systems and methods for processing data, and more particularly to systems and methods for scaling in a data processing system.

Data processing systems often include one or more data detector circuits and data decoder circuits. The output of each of the circuits may be fed to another of the circuits for additional processing. In some cases, the additional processing does not converge on a desired result, and in some cases may diverge from a desired result. In such cases, data processing performance may be dramatically reduced.

Hence, for at least the aforementioned reasons, there exists a need in the art for advanced systems and methods for data processing.

### BRIEF SUMMARY OF THE INVENTION

The present invention is related to systems and methods for processing data, and more particularly to systems and methods for scaling in a data processing system.

Various embodiments of the present invention provide data processing systems. Such data processing systems include: a data detector circuit, a symbol selective scaling circuit, and a data decoder circuit. The data detector circuit is operable to apply a data detection algorithm to a data input guided by a first data set derived from a decoded output to yield a detected output. The symbol selective scaling circuit is operable to selectively scale one or more symbols of a second data set derived from the detected output to yield a scaled data set. The data decoder circuit operable to apply a data decode algorithm to a third data set derived from the scaled data set to yield the decoded output.

In some instances of the aforementioned embodiments, the system is implemented as part of an integrated circuit. In various instances of the aforementioned embodiments, the system is implemented as part of a storage device. In other instances of the aforementioned embodiments, the system is implemented as part of either a wired or wireless communication device. In some cases, the first data set is a de-interleaved version of the decoded output, the second data set is the detected output less the first data set, and the third data set is an interleaved version of the scaled data set.

In various instances of the aforementioned embodiments, the data decode algorithm is a non-binary low density parity check algorithm. In some such instances, the second data set includes a number of two bit symbols each having the following four values: L0 corresponding to a likelihood that a value ‘00’ is an appropriate hard decision; L1 corresponding to a likelihood that a value ‘01’ is the appropriate hard decision; L2 corresponding to a likelihood that a value ‘10’ is the appropriate hard decision; and L3 corresponding to a likelihood that a value ‘11’ is the appropriate hard decision. In some cases, the symbol selective scaling circuit operable to selectively scale one or more symbols of the second data set to yield the scaled data set in accordance with the following equations:
L0 of a scaled data set [i]=L0 of the second data set [i] * a SALAR;
L1 of the scaled data set [i]=L1 of the second data set [i] * the SCALAR;
L2 of the scaled data set [i]=L2 of the second data set [i] * the SCALAR;
L3 of the scaled data set [i]=L3 of the second data set [i] * the SCALAR.

In such cases, the variable [i] indicates a given symbol of the scaled data set and the second data set. In some such cases, the SCALAR is a programmable value. In one or more instances of the aforementioned embodiments, the symbol selective scaling circuit is operable to scale a given symbol of the second data set based at least in part on the maximum one of L0, L1, L2, L3 of the first data set being different from the maximum one of L0, L1, L2, L3 of the second data set. In other instances of the aforementioned embodiments, the symbol selective scaling circuit is operable to scale a given symbol of the second data set based at least in part on the maximum one of L0, L1, L2, L3 of the second data set being different from the maximum one of L0, L1, L2, L3 of the detected output. In various instances of the aforementioned embodiments, the symbol selective scaling circuit is operable to scale a given symbol of the second data set based at least in part on a first number of violated checks from the data decoder circuit for a preceding application of the data decoding algorithm by the data decoder circuit being greater than a second number of violated checks from the data decoder circuit for a current application of the data decoding algorithm by the data decoder circuit.

Other embodiments of the present invention provide data storage devices that include: a storage medium maintaining a representation of an input data set; an analog front end circuit operable to sense the representation of the input data set and to provide the input data set as an analog input; an analog to digital converter circuit operable to convert the analog input into a series of digital samples; an equalizer circuit operable to receive the series of digital samples to yield a data input; and a data processing circuit. The data processing circuit includes: a data detector circuit operable to apply a data detection algorithm to the data input guided by a first data set derived from a decoded output to yield a detected output; a symbol selective scaling circuit operable to selectively scale one or more symbols of a second data set derived from the detected output to yield a scaled data set; and a data decoder circuit operable to apply a data decode algorithm to a third data set derived from the scaled data set to yield the decoded output.

Yet other embodiments of the present invention provide data transmission devices that include a receiver. The receiver includes a data processing circuit that comprises: a data detector circuit operable to apply a data detection algorithm to the data input guided by a first data set derived from a decoded output to yield a detected output; a symbol selective scaling circuit operable to selectively scale one or more symbols of a second data set derived from the detected output to yield a scaled data set; and a data decoder circuit operable to apply a data decode algorithm to a third data set derived from the scaled data set to yield the decoded output.

This summary provides only a general outline of some embodiments of the invention. Many other objects, features, advantages and other embodiments of the invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 depicts a data processing circuit including symbol selective scaling circuitry in accordance with some embodiments of the present invention;

FIG. 2 depicts a communication system including symbol selective scaling circuitry in accordance with one or more embodiments of the present invention

FIG. 3 shows a storage system including symbol selective scaling circuitry in accordance with one or more embodiments of the present invention; and

FIG. 4 is a flow diagram showing a method in accordance with some embodiments of the present invention for symbol selective scaling in accordance with various embodiments of the present invention.

### DETAILED DESCRIPTION OF THE INVENTION

The present invention is related to systems and methods for processing data, and more particularly to systems and methods for scaling in a data processing system.

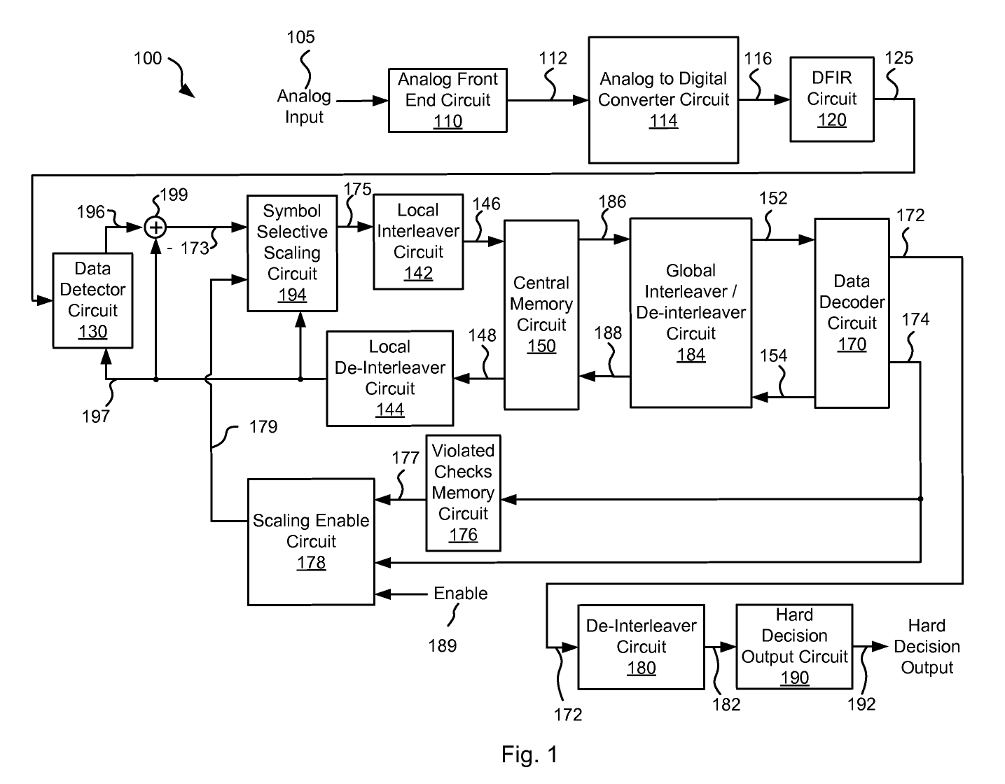

Turning to FIG. 1, a data processing circuit 100 is shown that includes symbol selective scaling circuitry that is operable to monitor selectively scale a data detector output on a symbol by symbol basis in accordance with some embodiments of the present invention. Data processing circuit 100 includes an analog front end circuit 110. Analog front end circuit 110 may include, but is not limited to, an analog filter and an amplifier circuit as are known in the art. Based upon the disclosure provided herein, one of ordinary skill in the art will recognize a variety of circuitry that may be included as part of analog front end circuit 110. In some cases, the gain of a variable gain amplifier included as part of analog front circuit 110 may be modifiable, and the cutoff frequency and boost of an analog filter included in analog front end circuit 110 may be modifiable. Analog front end circuit 110 receives and processes an analog signal 105, and provides a processed analog signal 112 to an analog to digital converter circuit 114. In some cases, analog signal 105 is derived from a read/write head assembly (not shown) that is disposed in relation to a storage medium (not shown). In other cases, analog signal 105 is derived from a receiver circuit (not shown) that is operable to receive a signal from a transmission medium (not shown). The transmission medium may be wireless or wired such as, but not limited to, cable or optical connectivity. Based upon the disclosure provided herein, one of ordinary skill in the art will recognize a variety of sources from which analog input 105 may be derived.

Analog to digital converter circuit 114 converts processed analog signal 112 into a corresponding series of digital samples 116. Analog to digital converter circuit 114 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 116 are provided to an equalizer circuit 120. Equalizer circuit 120 applies an equalization algorithm to digital samples 116 to yield an equalized output 125. In some embodiments of the present invention, equalizer circuit 120 is a digital finite impulse response filter circuit as are known in the art. Equalized output 125 is provided to a data detector circuit 130. In some cases, equalizer 120 includes sufficient memory to maintain one or more codewords until a data detector circuit 130 is available for processing.

Data detector circuit 130 is operable to apply a data detection algorithm to a received codeword or data set, and in some cases data detector circuit 130 can process two or more codewords in parallel. The received codeword or data set includes a number of multi-bit symbols. In one particular embodiment of the present invention, the multi-bit symbols are two bit symbols that include four values for each two bit symbol (i.e., ‘00’, ‘01’, ‘10’, ‘11’). In such a case, a detected output 196 from data detector circuit 130 includes four soft decision values (L0 corresponding to a likelihood that ‘00’ is the appropriate hard decision, L1 corresponding to a likelihood that ‘01’ is the appropriate hard decision, L2 corresponding to a likelihood that ‘10’ is the appropriate hard decision, and L3 corresponding to a likelihood that ‘11’ is the appropriate hard decision). In another embodiment of the present invention, the multi-bit symbols are three bit symbols that include eight values for each three bit symbol (i.e., ‘000’, ‘001’, ‘010’, ‘011’, ‘100’, ‘101’, ‘110’, ‘111’). In such a case, detected output 196 from data detector circuit 130 includes four soft decision values (L0 corresponding to a likelihood that ‘000’ is the appropriate hard decision, L1 corresponding to a likelihood that ‘001’ is the appropriate hard decision, L2 corresponding to a likelihood that ‘010’ is the appropriate hard decision, L3 corresponding to a likelihood that ‘011’ is the appropriate hard decision, L4 corresponding to a likelihood that ‘100’ is the appropriate hard decision, L5 corresponding to a likelihood that ‘101’ is the appropriate hard decision, L6 corresponding to a likelihood that ‘110’ is the appropriate hard decision, L7 corresponding to a likelihood that ‘111’ is the appropriate hard decision). Based upon the disclosure provided herein, one of ordinary skill in the art will recognize a number of different symbol sizes that may be used in relation to different embodiments of the present invention.

In some embodiments of the present invention, data detector circuit 130 is a Viterbi algorithm data detector circuit as are known in the art. In other embodiments of the present invention, data detector circuit 130 is a maximum a posteriori data detector circuit as are known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, bi-direction Viterbi detection algorithm or bi-direction Viterbi algorithm detector circuit. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments of the present invention. Data detector circuit 130 is started based upon availability of a data set from equalizer circuit 120 or from a central memory circuit 150.

Upon completion, data detector circuit 130 provides detector output 196 to a summation circuit 199 that subtracts de-interleaved output 197 on a symbol by symbol basis to yield a symbol output 173. Symbol output 173 is provided to a symbol selective scaling circuit 194 that selectively scales one or more symbols within symbol output 173 depending upon a combination of a codeword enable signal 179 and de-interleaved output 197. Symbol selective scaling circuit 194 provides a series of selectively scaled symbols as a scaled detected output 175 to a local interleaver circuit 142. In some embodiments of the present invention, symbol selective scaling circuit 194 may perform the scaling to yield scaled detected output 175 in accordance with the following pseudo-code based upon two bit symbols and a comparison of symbol output 173 with de-interleaved output 197:

```
If (codeword enable signal 179 == ‘1’) /*If scaling is enabled by an
enable circuit 178) */
{
  For (i=0 to END OF CODEWORD) /* for each symbol of symbol
output 173 */
  {
    If (ArgMax(L0, L1, L2, L3) of de-interleaver output 197 NOT
      EQUAL to ArgMax(L0, L1, L2, L3) of symbol output 173)
    {
      /* Scale the selected symbol */
      L0 of scaled detected output [i] 175 = L0 of symbol output
      173 [i] * SCALAR;
      L1 of scaled detected output [i] 175 = L1 of symbol output
      173 [i] * SCALAR;
      L2 of scaled detected output [i] 175 = L2 of symbol output
      173 [i] * SCALAR;
      L3 of scaled detected output [i] 175 = L3 of symbol output
      173 [i] * SCALAR
    }
    Else
    {
      /* Do not scale the selected symbol */
      L0 of scaled detected output [i] 175 = L0 of symbol output 173 [i];
      L1 of scaled detected output [i] 175 = L1 of symbol output 173 [i];
      L2 of scaled detected output [i] 175 = L2 of symbol output 173 [i];
      L3 of scaled detected output [i] 175 = L3 of symbol output 173 [i]
    }
  }
}
Else /*If scaling is not enabled by scaling enable circuit 178) */
{
  For (i=0 to END OF CODEWORD)
  {
    L0 of scaled detected output [i] 175 = L0 of symbol output 173 [i];
    L1 of scaled detected output [i] 175 = L1 of symbol output 173 [i];
    L2 of scaled detected output [i] 175 = L2 of symbol output 173 [i];
    L3 of scaled detected output [i] 175 = L3 of symbol output 173 [i]
  }
}
```

In the aforementioned pseudo-code, the function “ArgMax” returns a pointer indicating which of the values L0-L3 was the highest. Thus, the comparison of ArgMax of symbol output 173 [i] with de-interleaver output 197 [i] compares whether the same symbol (one of L0-L3) is returned for both symbol output 173 and de-interleaver output 197. Of note, the preceding pseudo-code may be expanded for use in relation to symbols of three or more bits. The value of SCALAR may be fixed, or may be user programmable. In one particular embodiment of the present invention, the value of SCALAR is 0.5.

In other embodiments of the present invention, symbol selective scaling circuit 194 may perform the scaling to yield scaled detected output 175 in accordance with the following pseudo-code based upon two bit symbols and a comparison of symbol output 173 with detected output 196:

```
If (codeword enable signal 179 == ‘1’) /*If scaling is enabled by enable
circuit 178) */
{
  For (i=0 to END OF CODEWORD) /* for each symbol of symbol
  output 173 */
  {
    If (ArgMax(L0, L1, L2, L3) of detected output 196 [i] NOT
      EQUAL to ArgMax(L0, L1, L2, L3) of symbol output 173 [i])
    {
      /* Scale the selected symbol */
      L0 of scaled detected output [i] 175 = L0 of symbol output
      173 [i] * SCALAR;
      L1 of scaled detected output [i] 175 = L1 of symbol output
      173 [i] * SCALAR;
      L2 of scaled detected output [i] 175 = L2 of symbol output
      173 [i] * SCALAR;
      L3 of scaled detected output [i] 175 = L3 of symbol output
      173 [i] * SCALAR
    }
    Else
    {
      /* Do not scale the selected symbol */
      L0 of scaled detected output [i] 175 = L0 of symbol output 173 [i];
      L1 of scaled detected output [i] 175 = L1 of symbol output 173 [i];
      L2 of scaled detected output [i] 175 = L2 of symbol output 173 [i];
      L3 of scaled detected output [i] 175 = L3 of symbol output 173 [i]
    }
  }
}
Else /*If scaling is not enabled by scaling enable circuit 178) */
{
  For (i=0 to END OF CODEWORD)
  {
    L0 of scaled detected output [i] 175 = L0 of symbol output 173 [i];
    L1 of scaled detected output [i] 175 = L1 of symbol output 173 [i];
    L2 of scaled detected output [i] 175 = L2 of symbol output 173 [i];
    L3 of scaled detected output [i] 175 = L3 of symbol output 173 [i]
  }
}
```

Again, the function “ArgMax” returns a pointer indicating which of the values L0-L3 was the highest. Thus, the comparison of ArgMax of symbol output 173 [i] with detected output 196 [i] compares whether the same symbol (one of L0-L3) is returned for both symbol output 173 and detected output 196.

In the aforementioned embodiments, the scaling is performed on all of the symbols for a particular instance (i.e., [i]) of symbol output 173 (i.e., all of L0-L3 are scaled). In other embodiments of the present invention, only the soft data of symbol output 173 having the maximum value in detected output 196 is scaled (i.e., only one of L0-L3 having the maximum value is scaled). Assume the symbol output 173 that has the maximum value in detected output 196 is A, and that in symbol output 173 it is B. Where A is not equal to B, then in one case all symbols in symbol output 173 are scaled, while in another case, only symbol A in symbol output 173 is scaled. Local interleaver circuit 142 shuffles sub-portions (i.e., local chunks) of scaled detected output 175 to yield an interleaved codeword 146 that is stored to central memory circuit 150. Local interleaver circuit 142 may be any circuit known in the art that is capable of shuffling data sets to yield a re-arranged data set.

Once data decoder circuit 170 is available, a previously stored interleaved codeword 146 is accessed from central memory circuit 150 as a decoder input 152 via a global interleaver/de-interleaver circuit 184. In particular, global interleaver/de-interleaver circuit 184 performs a global data shuffling on a data set 186 retrieved from central memory circuit 150 to yield a decoder input 152. Data decoder circuit 170 applies a data decode algorithm to decoder input 152 to yield a decoded output. In some embodiments of the present invention, the data decode algorithm is a non-binary low density parity check algorithm as are known in the art. Based upon the disclosure provided herein, one of ordinary skill in the art will recognize other decode algorithms that may be used in relation to different embodiments of the present invention. As the data decode algorithm completes on a given data set, it is determined whether the decoded output converged (i.e., the resulting data set matches the originally written data set as indicated by the lack of parity errors). Where it is determined that the decoded output converged, the resulting decoded data set is provided as a hard decision output 172 to a de-interleaver circuit 180. De-interleaver circuit 180 rearranges the data to reverse both the global and local interleaving applied to the data to yield a de-interleaved output 182. De-interleaved output 182 is provided to a hard decision output circuit 190. Hard decision output circuit 190 is operable to re-order data sets that may complete out of order back into their original order. The originally ordered data sets are then provided as a hard decision output 192.

Alternatively, where it is determined that the data decode algorithm failed to converge (i.e., there are remaining parity errors), a completed data set 154 is globally de-interleaved by global interleaver/de-interleaver circuit 184 which essentially reverses the earlier applied global interleaving (i.e., shuffling) to yield a de-interleaved output 188. De-interleaved output 188 is stored to central memory circuit 150. In addition, a number of violated checks 174 (i.e., the number of remaining parity errors in completed data set 154) is compared with a number of violated checks 177 from a preceding global iteration (i.e., a pass through both data detector circuit 130 and data decoder circuit 170) previously stored in a violated checks memory circuit 174. Where the number of violated checks is greater for a subsequent global iteration than for a prior global iteration (i.e., violated checks 174 is greater than violated checks 177) and it is not the first global iteration and a user enable 189 is asserted, then scaling enable circuit 178 sets codeword enable signal 179 equal to ‘1’. Otherwise, scaling enable circuit 178 sets codeword enable signal 179 equal to ‘0’. After the comparison, violated checks 174 is stored to violated checks memory circuit 176 for use on a subsequent global iteration. The following pseudo-code describes the operation of violated checks memory circuit 176 and scaling enable circuit 178:

```
If (a second or later global iteration && enable 189 is asserted)
{
  If (violated checks 174 > violated checks 177)
  {
    codeword enable signal 179 = ‘1’
  }
  Else
  {
    codeword enable signal 179 = ‘0’
  }
}
Else
{
  codeword enable signal 179 = ‘0’
}
```

Once data detector circuit 130 is available, a previously stored decoder output 148 is accessed from central memory circuit 150 and locally de-interleaved by a local de-interleaver circuit 144. Local de-interleaver circuit 144 re-arranges decoder output 148 to reverse the shuffling originally performed by local interleaver circuit 142. A resulting de-interleaved output 197 is provided to data detector circuit 130.

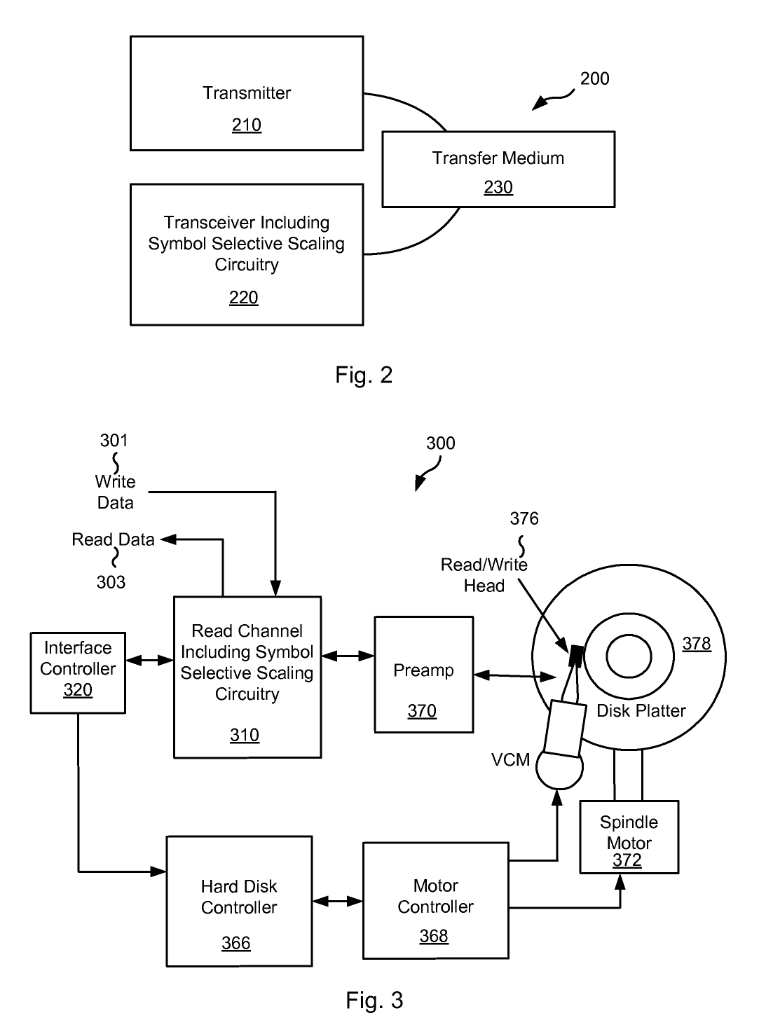

Turning to FIG. 2, a communication system 200 including a transceiver 220 having symbol selective scaling circuitry in accordance with one or more embodiments of the present invention. Communication system 200 includes a transmitter 210 that is operable to transmit encoded information via a transfer medium 230 as is known in the art. The encoded data is received from transfer medium 230 by transceiver 220. Transceiver 2420 incorporates symbol selective scaling circuitry. While processing received data, received data is converted from an analog signal to a series of corresponding digital samples, and the digital samples are equalized to yield an equalized output. The equalized output is then provided to a data processing circuit including both a data detector circuit and a data decoder circuit. Data is passed between the data decoder and data detector circuit via a central memory allowing for variation between the number of processing iterations that are applied to different data sets. It should be noted that transfer medium 230 may be any transfer medium known in the art including, but not limited to, a wireless medium, an optical medium, or a wired medium. Based upon the disclosure provided herein, one of ordinary skill in the art will recognize a variety of transfer mediums that may be used in relation to different embodiments of the present invention.

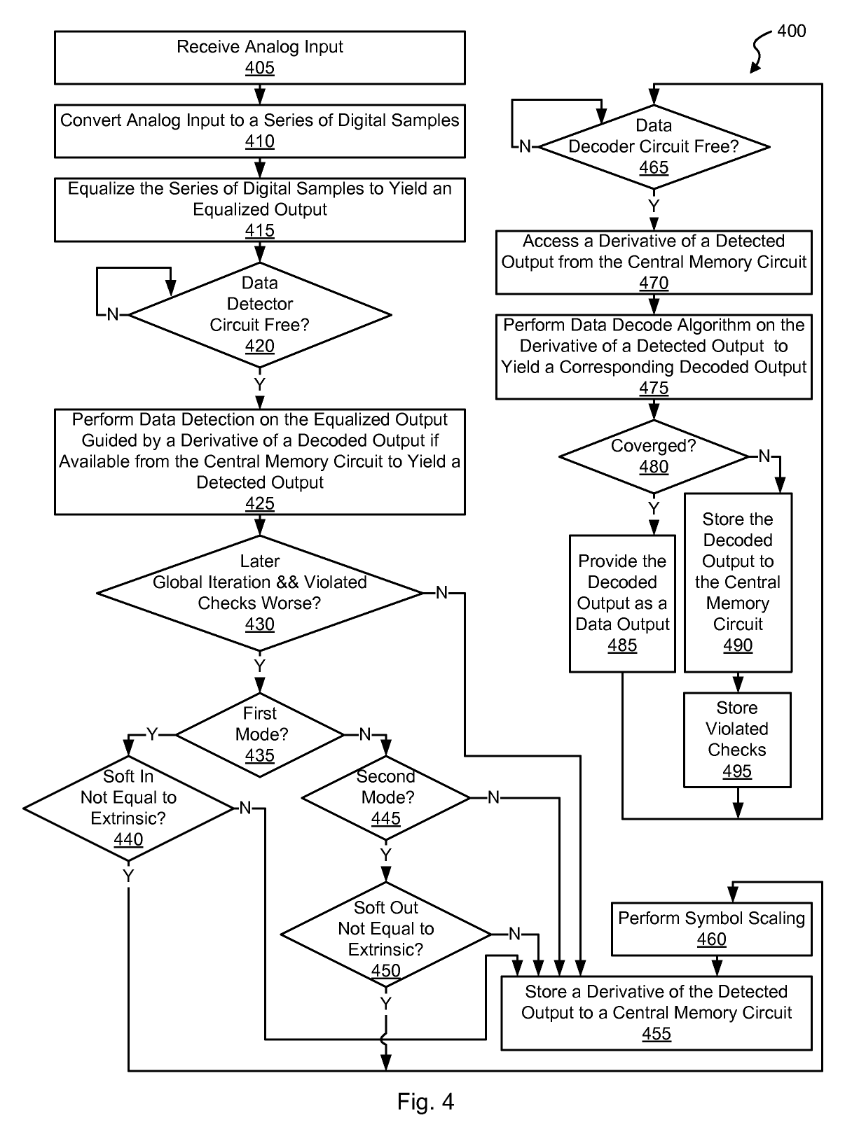

During operation, the symbol selective scaling circuitry may scale one or more symbols of a given codeword depending upon various conditions in an effort to improve data processing performance. Such symbols may be two or more bits. The symbol selective scaling circuitry may be implemented similar to that discussed above in relation to FIG. 1, and/or may operate similar to that discussed below in relation to FIG. 4.

Turning to FIG. 3, a storage device 300 including symbol selective scaling circuitry is shown in accordance with one or more embodiments of the present invention. Storage system 300 may be, for example, a hard disk drive. Storage system 300 also includes a preamplifier 370, an interface controller 320, a hard disk controller 366, a motor controller 368, a spindle motor 372, a disk platter 378, and a read/write head assembly 376. Interface controller 320 controls addressing and timing of data to/from disk platter 378. The data on disk platter 378 consists of groups of magnetic signals that may be detected by read/write head assembly 376 when the assembly is properly positioned over disk platter 378. In one embodiment, disk platter 378 includes magnetic signals recorded in accordance with either a longitudinal or a perpendicular recording scheme.

In a typical read operation, read/write head assembly 376 is accurately positioned by motor controller 368 over a desired data track on disk platter 378. Motor controller 368 both positions read/write head assembly 376 in relation to disk platter 378 and drives spindle motor 372 by moving read/write head assembly to the proper data track on disk platter 378 under the direction of hard disk controller 366. Spindle motor 372 spins disk platter 378 at a determined spin rate (RPMs). Once read/write head assembly 378 is positioned adjacent the proper data track, magnetic signals representing data on disk platter 378 are sensed by read/write head assembly 376 as disk platter 378 is rotated by spindle motor 372. The sensed magnetic signals are provided as a continuous, minute analog signal representative of the magnetic data on disk platter 378. This minute analog signal is transferred from read/write head assembly 376 to read channel circuit 310 via preamplifier 370. Preamplifier 370 is operable to amplify the minute analog signals accessed from disk platter 378. In turn, read channel circuit 310 decodes and digitizes the received analog signal to recreate the information originally written to disk platter 378. This data is provided as read data 303 to a receiving circuit. A write operation is substantially the opposite of the preceding read operation with write data 301 being provided to read channel circuit 310. This data is then encoded and written to disk platter 378.

During operation, the symbol selective scaling circuitry may scale one or more symbols of a given codeword depending upon various conditions in an effort to improve data processing performance. Such symbols may be two or more bits. The symbol selective scaling circuitry may be implemented similar to that discussed above in relation to FIG. 1, and/or may operate similar to that discussed below in relation to FIG. 4.

It should be noted that storage system may utilize SATA, SAS or other storage technologies known in the art. Also, it should be noted that storage system 300 may be integrated into a larger storage system such as, for example, a RAID (redundant array of inexpensive disks or redundant array of independent disks) based storage system. It should also be noted that various functions or blocks of storage system 300 may be implemented in either software or firmware, while other functions or blocks are implemented in hardware.

Turning to FIG. 4, a flow diagram 400 shows a method in accordance with some embodiments of the present invention for symbol selective scaling in accordance with various embodiments of the present invention. Following flow diagram 400, an analog input signal is received (block 405). The analog input may be derived from, for example, a storage medium or a data transmission channel. Based upon the disclosure provided herein, one of ordinary skill in the art will recognize a variety of sources of the analog input. The analog input is converted to a series of digital samples (block 410). This conversion may be done using an analog to digital converter circuit or system as are known in the art. Of note, any circuit known in the art that is capable of converting an analog signal into a series of digital values representing the received analog signal may be used. The resulting digital samples are equalized to yield an equalized output (block 415). In some embodiments of the present invention, the equalization is done using a digital finite impulse response circuit as are known in the art. Based upon the disclosure provided herein, one of ordinary skill in the art will recognize a variety of equalizer circuits that may be used in place of such a digital finite impulse response circuit to perform equalization in accordance with different embodiments of the present invention.

It is determined whether a data detector circuit is available (block 420). Where a data detector circuit is available (block 420), a data detection algorithm is applied to the equalized output guided by a de-interleaved codeword (i.e., a derivative of a decoded output) where such a de-interleaved codeword corresponding to the equalized output is available (i.e., the second and later iterations through the data detector circuit and the data decoder circuit). This process yields a detected output (block 425). In some embodiments of the present invention, data detection algorithm is a Viterbi algorithm as are known in the art. In other embodiments of the present invention, the data detection algorithm is a maximum a posteriori data detector circuit as are known in the art.

It is determined whether the currently progressing data detection process is part of a second or later global iteration for the given codeword, and whether the number of violated checks at the end of a data decoding process is increasing (block 430). Where both conditions are not true (block 430), a derivative of the detected output is stored to a central memory circuit (block 455). In some cases, the derivative of the detected output is a locally interleaved version of the detected output.

Alternatively, where both conditions are not true (block 430), it is determined whether a first mode of operation is selected (block 435). The first mode of operation relies on a comparison between a soft output and an extrinsic output. In contrast, a second mode of operation relies on a comparison between a soft input and an extrinsic output. Where the first mode of operation is selected (block 435), it is determined whether the current instance ([i]) of the soft output is equal to the corresponding instance ([i]) of the extrinsic output (block 440). Comparison of the instances is done on a symbol by symbol basis. Using data processing circuit 100 as an example, the soft output corresponds to detected output 196, and the extrinsic output corresponds to symbol output 173. Where the two instances are equal (block 440), a derivative of the detected output is stored to a central memory circuit (block 455). Alternatively, where the two instances are not equal (block 640), the symbol corresponding to the particular instance ([i]) is scaled (block 660) and subsequently stored to the central memory circuit (block 455). In some embodiments of the present invention, the scaling is done to all values for a given symbol. Thus, for example, where two bit symbols having four values, L0-L3, for each symbol (L0 corresponding to a likelihood that ‘00’ is the appropriate hard decision, L1 corresponding to a likelihood that ‘01’ is the appropriate hard decision, L2 corresponding to a likelihood that ‘10’ is the appropriate hard decision, and L3 corresponding to a likelihood that ‘11’ is the appropriate hard decision), the symbol scaling may be done in accordance with the following pseudo-code:
L0 of a scaled output [i]=L0 of extrinsic output [i] * SCALAR;
L1 of a scaled output [i]=L1 of extrinsic output [i] * SCALAR;
L2 of a scaled output [i]=L2 of extrinsic output [i] * SCALAR;
L3 of a scaled output [i]=L3 of extrinsic output [i] * SCALAR;

Of note, the preceding pseudo-code may be expanded for use in relation to symbols of three or more bits. The value of SCALAR may be fixed, or may be user programmable. In one particular embodiment of the present invention, the value of SCALAR is 0.5. In the preceding embodiment of the present invention, the scaling is performed on all of the symbols for a particular instance ([i]). In other embodiments of the present invention, only the soft data of symbol having the maximum value is scaled (i.e., only one of L0-L3 having the maximum value is scaled).

Alternatively, where the first mode is not selected (block 435), it is determined whether a second mode is selected (block 445). Where the second mode of operation is not selected (block 645), a derivative of the detected output is stored to a central memory circuit (block 455). Where the second mode of operation is selected (block 445), it is determined whether the current instance ([i]) of the soft input is equal to the corresponding instance ([i]) of the extrinsic output (block 450). Comparison of the instances is done on a symbol by symbol basis. Using data processing circuit 100 as an example, the soft input corresponds to de-interleaved output 197, and the extrinsic output corresponds to symbol output 173. Where the two instances are equal (block 450), a derivative of the detected output is stored to a central memory circuit (block 455). Alternatively, where the two instances are not equal (block 450), the symbol corresponding to the particular instance ([i]) is scaled (block 460) and subsequently stored to the central memory circuit (block 455). In some embodiments of the present invention, the scaling is done to all values for a given symbol. Thus, for example, where two bit symbols having four values, L0-L3, for each symbol (L0 corresponding to a likelihood that ‘00’ is the appropriate hard decision, L1 corresponding to a likelihood that ‘01’ is the appropriate hard decision, L2 corresponding to a likelihood that ‘10’ is the appropriate hard decision, and L3 corresponding to a likelihood that ‘11’ is the appropriate hard decision), the symbol scaling may be done in accordance with the following pseudo-code:
L0 of a scaled output [i]=L0 of an extrinsic output [i] * SCALAR;
L1 of the scaled output [i]=L1 of the extrinsic output [i] * SCALAR;
L2 of the scaled output [i]=L2 of the extrinsic output [i] * SCALAR;
L3 of the scaled output [i]=L3 of the extrinsic output [i] * SCALAR;
   Of note, the preceding pseudo-code may be expanded for use in relation to symbols of three or more bits. The value of SCALAR may be fixed, or may be user programmable. In one particular embodiment of the present invention, the value of SCALAR is 0.5. In the preceding embodiment of the present invention, the scaling is performed on all of the symbols for a particular instance ([i]). In other embodiments of the present invention, only the soft data of symbol having the maximum value is scaled (i.e., only one of L0-L3 having the maximum value is scaled).

In parallel to the previously discussed processing, it is determined whether a data decoder circuit is available (block 465). Where the data decoder circuit is available (block 465) a previously stored derivative of the detected output is accessed from the central memory (block 470). A decode algorithm is applied to the accessed derivative of the detected output to yield a corresponding decoded output (block 475). In some embodiments of the present invention, the data decode algorithm is a non-binary low density parity check algorithm as are known in the art. Based upon the disclosure provided herein, one of ordinary skill in the art will recognize other decode algorithms that may be used in relation to different embodiments of the present invention. It is determined whether the decode algorithm converged (i.e., the original data set is identified) (block 480). Where the data decode algorithm converged (block 480), the decoded output is provided as a data output (block 485). Otherwise, where the data decode algorithm failed to converge (block 480), the decoded output (or a derivative of the decoded output such as, for example, a globally de-interleaved version of the decoded output) is stored back to the central memory circuit for a subsequent global iteration (i.e., processing through both the data detection algorithm and the data decode algorithm) (block 490). In addition, the number of remaining violated checks (i.e., the number of remaining parity check equations that are not correct) is stored for use in relation to block 430 (block 495).

It should be noted that the various blocks discussed in the above application may be implemented in integrated circuits along with other functionality. Such integrated circuits may include all of the functions of a given block, system or circuit, or only a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A data processing system, the circuit comprising:
a data detector circuit operable to apply a data detection algorithm to a data input guided by a first data set derived from a decoded output to yield a detected output;
a symbol selective scaling circuit operable to selectively scale one or more symbols of a second data set derived from the detected output to yield a scaled data set; and
a data decoder circuit operable to apply a data decode algorithm to a third data set derived from the scaled data set to yield the decoded output.

2. The data processing system of claim 1, wherein the first data set is a de-interleaved version of the decoded output.

3. The data processing system of claim 1, wherein the second data set is the detected output less the first data set.

4. The data processing system of claim 1, wherein the third data set is an interleaved version of the scaled data set.

5. The data processing system of claim 1, wherein the data decode algorithm is a non-binary low density parity check algorithm.

6. The data processing system of claim 5, wherein the second data set includes a number of two bit symbols each having the following four values:
L0 corresponding to a likelihood that a value ‘00’ is an appropriate hard decision;
L1 corresponding to a likelihood that a value ‘01’ is the appropriate hard decision;
L2 corresponding to a likelihood that a value ‘10’ is the appropriate hard decision; and
L3 corresponding to a likelihood that a value ‘11’ is the appropriate hard decision.

7. The data processing system of claim 6, wherein the symbol selective scaling circuit operable to selectively scale one or more symbols of the second data set to yield the scaled data set in accordance with the following equations:
L0 of a scaled data set [i]=L0 of the second data set [i] * a SCALAR;
L1 of the scaled data set [i]=L1 of the second data set [i] * the SCALAR;
L2 of the scaled data set [i]=L2 of the second data set [i] * the SCALAR;
L3 of the scaled data set [i]=L3 of the second data set [i] * the SCALAR; and
wherein the variable [i] indicates a given symbol of the scaled data set and the second data set.

8. The data processing system of claim 7, wherein the SCALAR is a programmable value.

9. The data processing system of claim 6, wherein the symbol selective scaling circuit is operable to scale a given symbol of the second data set based at least in part on the maximum one of L0, L1, L2, L3 of the first data set being different from the maximum one of L0, L1, L2, L3 of the second data set.

10. The data processing system of claim 6, wherein the symbol selective scaling circuit is operable to scale a given symbol of the second data set based at least in part on the maximum one of L0, L1, L2, L3 of the second data set being different from the maximum one of L0, L1, L2, L3 of the detected output.

11. The data processing system of claim 1, wherein the symbol selective scaling circuit is operable to scale a given symbol of the second data set based at least in part on a first number of violated checks from the data decoder circuit for a preceding application of the data decoding algorithm by the data decoder circuit being greater than a second number of violated checks from the data decoder circuit for a current application of the data decoding algorithm by the data decoder circuit.

12. The data processing system of claim 1, wherein the system is implemented as part of an integrated circuit.

13. The data processing system of claim 1, wherein the system is implemented as part of a device selected from a group consisting of: a storage device, a wired communication device, and a wireless communication device.

14. A data storage device, the storage device comprising:
a storage medium maintaining a representation of an input data set;
an analog front end circuit operable to sense the representation of the input data set and to provide the input data set as an analog input;
an analog to digital converter circuit operable to convert the analog input into a series of digital samples;
an equalizer circuit operable to receive the series of digital samples to yield a data input; and
a data processing circuit including:
a data detector circuit operable to apply a data detection algorithm to the data input guided by a first data set derived from a decoded output to yield a detected output;
a symbol selective scaling circuit operable to selectively scale one or more symbols of a second data set derived from the detected output to yield a scaled data set; and
a data decoder circuit operable to apply a data decode algorithm to a third data set derived from the scaled data set to yield the decoded output.

15. The storage device of claim 1, wherein the data decode algorithm is a non-binary low density parity check algorithm.

16. The storage device of claim 15, wherein the second data set includes a number of two bit symbols each having the following four values:
L0 corresponding to a likelihood that a value ‘00’ is an appropriate hard decision;
L1 corresponding to a likelihood that a value ‘01’ is the appropriate hard decision;
L2 corresponding to a likelihood that a value ‘10’ is the appropriate hard decision; and
L3 corresponding to a likelihood that a value ‘11’ is the appropriate hard decision.

17. The storage device of claim 16, wherein the symbol selective scaling circuit is operable to scale a given symbol of the second data set based at least in part on a condition selected from a group consisting of:
the maximum one of L0, L1, L2, L3 of the first data set being different from the maximum one of L0, L1, L2, L3 of the second data set; and
the maximum one of L0, L1, L2, L3 of the second data set being different from the maximum one of L0, L1, L2, L3 of the detected output.

18. A data transmission device, the data transmission device comprising:
a receiver including a data processing circuit, wherein the data processing circuit includes:
a data detector circuit operable to apply a data detection algorithm to the data input guided by a first data set derived from a decoded output to yield a detected output;
a symbol selective scaling circuit operable to selectively scale one or more symbols of a second data set derived from the detected output to yield a scaled data set; and
a data decoder circuit operable to apply a data decode algorithm to a third data set derived from the scaled data set to yield the decoded output.

19. The data transmission device of claim 18, wherein the data decode algorithm is a non-binary low density parity check algorithm.

20. The data transmission device of claim 19, wherein the second data set includes a number of two bit symbols each having the following four values:
L0 corresponding to a likelihood that a value ‘00’ is an appropriate hard decision;
L1 corresponding to a likelihood that a value ‘01’ is the appropriate hard decision;
L2 corresponding to a likelihood that a value ‘10’ is the appropriate hard decision; and
L3 corresponding to a likelihood that a value ‘11’ is the appropriate hard decision.

21. The data transmission device of claim 20, wherein the symbol selective scaling circuit is operable to scale a given symbol of the second data set based at least in part on a condition selected from a group consisting of:
the maximum one of L0, L1, L2, L3 of the first data set being different from the maximum one of L0, L1, L2, L3 of the second data set; and
the maximum one of L0, L1, L2, L3 of the second data set being different from the maximum one of L0, L1, L2, L3 of the detected output.
